(19) United States
(12) Patent Application Publication
(10) Pub. No.: US 2009/0216573 A1
(43) Pub. Date: Aug. 27, 2009

(54) Method and device for automatic event detection and report generation

(75) Inventors: Jan Heiberg-Andersen, Västeräs (SE); Bertil Lundqvist, Västerás (SE); Lars Frisk, Västeràs (SE)

Correspondence Address: VENABLE LLP, P.O. BOX 34385, WASHINGTON, DC, 20043-9998, US

(73) Assignee: ABB RESEARCH LTD., Zurich (CH)

(21) Appl. No.: 11/919,908

(22) PCT Filed: May 4, 2006
(86) PCT No.: PCT/IB2006/002652

§ 371 Date: Feb. 5, 2009

Related U.S. Application Data
(60) Provisional application No. 60/677,341, filed on May 4, 2005.

(51) Int. Cl. G06Q 50/00; G06Q 10/00; G01R 31/00; G06F 19/00

(52) U.S. Cl. 705/7; 702/58

(57) ABSTRACT

A robot controller including a control unit and a portable operating device (TPU) for teaching and manually operating the robot. The TPU includes safety equipment, a safety TPU-part having a first communication unit and a main TPU-part having a third communication unit. The control unit includes a safety control part having a second communication unit and a main control part having a forth communication unit. The first and second communication units are arranged such that they form a first communication channel for transferring communication data including information regarding the status of safety equipment from the TPU to the control unit. The third and fourth communication units are arranged such that they form a second communication channel for transferring general communication data between the TPU and the control unit. Each of the main TPU-part, the safety TPU-part, the main control part, and the safety control part includes a central processing unit adapted for generating and/or handling the communication data. Each of the communication units is connected to a network. Each of the communication units forms a node in the network.

### FIELD OF THE INVENTION

The present invention relates to a method and a system operative to automatically detest events in electric power systems, generate reports including data regarding the events and forward the reports to one or more users.

### BACKGROUND OF THE INVENTION

Detecting the occurrence of events in power systems that can disrupt the power systems is of significant importance. Events can include faults, disturbances and/or other things. The electric power transmission and distribution system is relied upon to power homes and businesses. Disruptions in the system can cause social and economic disruption, resulting in great costs. Interconnections among power transmission and distribution networks can result in events, such as faults, causing disruptions at great distances from where they occur.

Electric power system utilities am controlled and protected by numeric relay protections. The numerical relay protection equipment continuously measures analog current and voltage data to assess the present condition of the system, that is, if the system is in a healthy or faulty state. Typically, the relay equipment is set to react on a faulty situation in order to clear the fault or at least to reduce damages to the system equipment.

The relay protection will be able to clear some faults; other faults will require human intervention. An example of a fault that relay protection is typically able to clear is a lightening strike, which results in a line to ground fault. Examples of faults requiring human intervention include an insulation fault in a cable and a tree failing on a power line.

Relay protection units can be equipped with a disturbance recorder to record measured data during a time window prior to a fault. For example, the COMTRADE format is a commonly accepted standard for such recorded disturbance data. Disturbances can also be recorded by special purpose disturbance reorder equipment. The recorded data is used to analyze the disturbance. Occasionally, such analysis is required to find the cause and solution of a persistent fault before the fault can be cleared by manual operation of the power electric equipment.

Disturbances in electric power supply systems generally lead to costs that can be substantial, for the utility, the customers, and other parties. The primary task of any utility management is to avoid disturbances in electrical power systems. Still, disturbances and faults occur. Reducing the time from fault to clearance is critical to reduce the negative effects to power dependent operations.

### SUMMARY OF THE INVENTION

One aspect of the present invention includes a method for automated analysis of events in an electric power system and dissemination of an event report. According to the method, a set of data is received including at least one parameter of an electric power system. At least one event is detected in the set of data. Selected data regarding the at least one event are isolated. At least one report is generated based on at least one predefined format. The at least one report is sent to at least one predefined group of users comprising at least one user.

Another aspect of the present invention provides a system for automated analysis of faults in an electric power system and dissemination of an event report. The system includes at least one calculation module operative to receive the at least one parameter, detect changes in the at least one parameter, determine whether an event has occurred and generate at least one event signal. The system also includes at least one report module operative to receive the at least one event signal from the at least one calculation module, generate at least one report comprising at least one selected parameter and forward the at least one report to at least one predefined group of users comprising at least one user.

Additional aspects of the present invention provide a computer program product that includes a computer readable medium and computer program instructions recorded on the computer readable medium and executable by a processor. The computer program instructions are for performing the steps of receiving a set of data comprising at least one parameter of an electric power system, detecting at least one event in the set of data, isolating selected data regarding the at least one event, generating at least one report based on at least one predefined format, and sending the at least one report to at least one predefined group of users comprising at least one user.

Further objectives and advantages, as well as the structure and function of exemplary embodiments will become apparent from a consideration of the description, drawings, and examples.

### BRIEF DESCRIPTION OF THE DRAWINGS

The foregoing and other features and advantages of the invention will be apparent from the following, more particular description of an exemplary embodiment of the invention, as illustrated in the accompanying drawings wherein like reference numbers generally indicate identical, functionally similar, and/or structurally similar elements.

FIG. 1 represents a schematic drawing illustrating elements of an embodiment of a system according to the present invention;

FIG. 2 represents a schematic drawing illustrating elements of another embodiment of a system according to the present invention;

FIG. 3 represents an embodiment of a time diagram showing data monitored according to an embodiment of the present invention;

FIG. 4 represents an embodiment of a zoomed view of a particular portion of the time diagram shown in FIG. 3;

FIG. 5 represents an embodiment of a diagram showing binary indications that may be monitored according to an embodiment of the present invention;

FIGS. 6a-l represent various portions of an embodiment of an event report according to the present invention where the event includes a disturbance; and

FIGS. 7 and 8 illustrate screen shots showing embodiments of a template editor according to the present invention.

### DETAILED DESCRIPTION OF EMBODIMENTS OF THE INVENTION

Embodiments of the invention ate discussed in detail below. In describing embodiments, specific terminology is employed for the sake of clarity. However, the invention is not intended to be limited to the specific terminology so selected. While specific exemplary embodiments are discussed, it should be understood that this is done for illustration purposes only. A person skilled in the relevant art will recognize that other components and configurations can be used without parting from the spirit and scope of the invention.

The purpose of analyzing disturbances in electrical power systems is to discover faults and weaknesses in the systems. In this way, the disturbance analysis, or functional analysis, provides a valuable basis for planning and designing extensions and improvements of the power system as well as its protection and control systems. It is important to obtain relevant information from every disturbance, independent of its complexity, to obtain sufficient basis for the analysis.

The majority of disturbances do not need deeper analysis. For example, when a power line is struck by lightning, the primary fault will disappear after tripping and sufficient reclaim time and auto-reclosure will occur. However, the time spent on evaluating such a disturbance will require disproportionate amount of time compared to more complicated disturbances when using present evaluations tools.

Given the economic and social problems that can result from disruptions of electric power systems, it would be desirable to provide quick notification to relevant people when a disturbance of the power system occurs. Embodiments of the present invention can provide such quick notification, thereby permitting action to be taken to rectify the situation. The present invention can achieve this though monitoring of electric power systems, analyzing results of the monitoring, identifying disturbances, generating disturbance reports and delivering the reports to users. The present invention may be initiated after detection of faults and initiated to generate and distribute reports. Through the automation of these processes, the present invention provides the possibility for the disturbance to rectified much sooner than would otherwise be possible, thereby minimizing and even possibly avoiding potential disruptions associated with disruptions. The present invention can speed up a process and eliminate risk associated with manual analysis of disturbance recordings and spotting relevant data in a large data sots.

Detecting disturbances, or events, can begin with monitoring one or more parameters of an electric power system. Among the parameters that may monitored are current and voltage. The present invention does not necessarily require any additional equipment. Existing monitoring equipment associated with existing relay products. The monitored values for the parameter(s) may be recorded.

Disturbance(s) in the parameter(s) may be detected. Detection of disturbance(s) may be detected by comparing values for the parameter(s) with baseline or target values or ranges of values. Trends in differences between monitored and baseline values or ranges of values may also be monitored. In some embodiments, values for monitored parameters within ranges of baseline values may be significant in identifying disturbance(s). In some eases, any difference in the monitored values of a parameter and a baseline value may indicate disturbance. In other situations, a deviation outside a range of values for the parameter may indicate a disturbance. It may be that a trend of monitored values over time with respect to a baseline value or range of values may be utilized to indicate a problem.

Examples of parameters that may be monitored include voltage, current, binary information regarding power system components, such as circuit breakers, disconnectors, grounding switches and other equipment, and/or other parameters that can indicate occurrence of an event in any aspect of a power system.

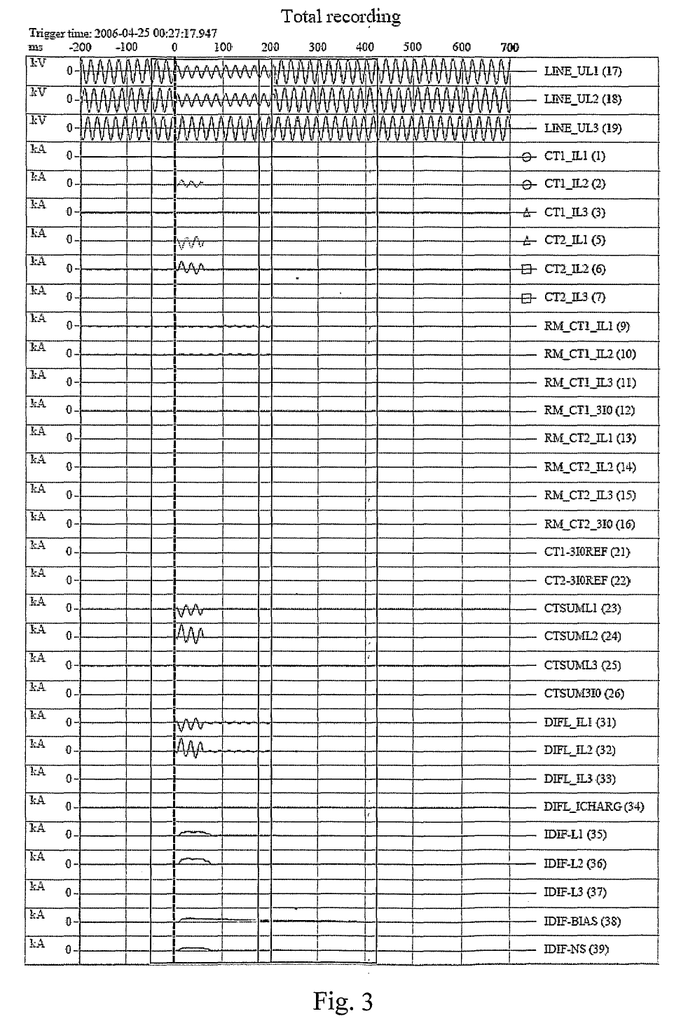

FIG. 3 represents an embodiment of a time diagram showing a recording including 32 analog channels. The recording time represents a 900 ms sampling period. As indicated by the rectangle from −50 ms to 200 ms a calculation module has detected an event and that will generate a zoomed view of data from this timeframe.

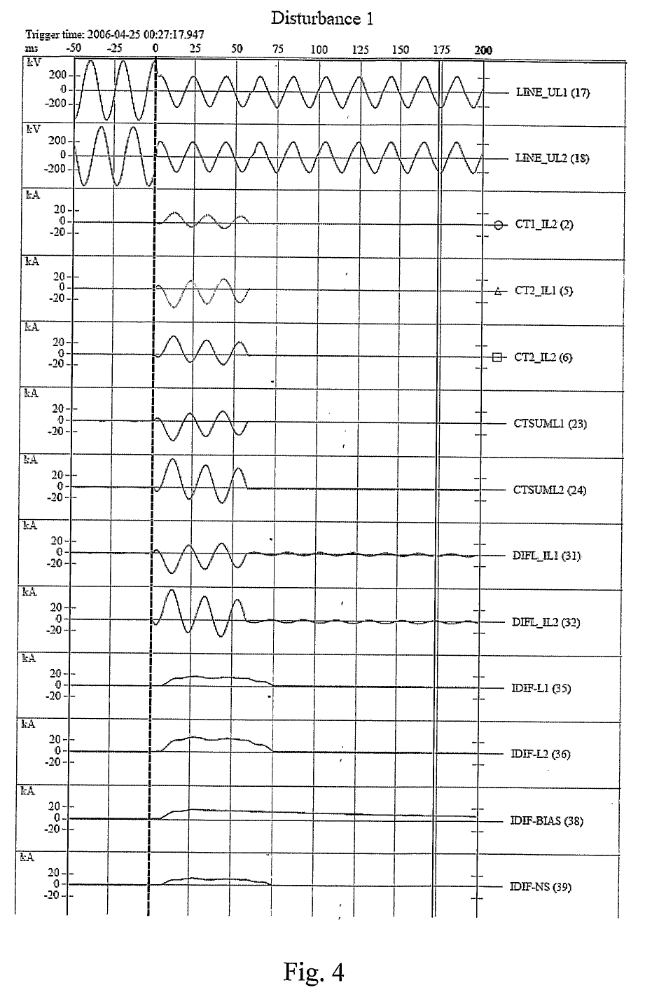

FIG. 4 represents an embodiment of a zoomed view of channels illustrated in the time diagram shown in FIG. 3 that were selected by the calculation module as interesting for the first event in the recording. LINE_UL1 and LINE_UL2 represent phase voltages measured in the recording IED. As seen in this view there is a drop in voltage of these two phases. CT1_IL2 CT2_IL1 and CT2_IL2 represent phase currents. It can be seen in FIG. 4 that there is a increase of current in these two phases. CTSUML1 and CTSUML2 represent calculated values of the current in the line. DIFL_IL1 and DIFL_IL2 represent differential current calculated by the line differential function and recorded by the disturbance recorder in the IED. This zoomed view illustrates that there is a difference in the current flowing in the different ends of the line. This means that there is a fault on the line.

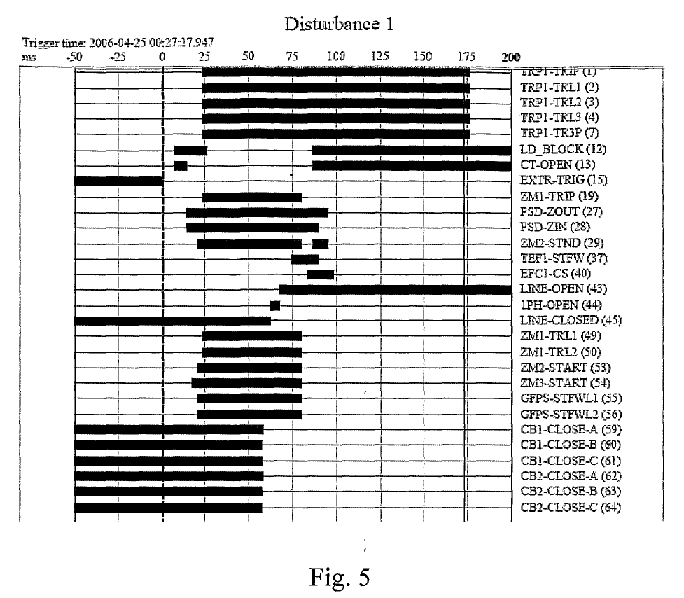

FIG. 5 illustrates binary indications from protection functions in an IED. The binary indications illustrate that the phase selection function has measured a fault in Phase A and Phase B (GFPS-SWFWL1 and L2) and that the distance function has measured a fault within protection zone 1 (ZM1-TRL1 and ZM1-TRL2).

Evaluation of the values of the monitored parameter(s) may be carried out with one or more intelligent electronic devices (IED's). Examples of IED's include line impedance protection, transformer protection, line differential protection, busbar differential protection, generator protection, bay control IED's among others. Also, dedicated disturbance recorders are also available on the market. One of these devices could be used as well.

If the evaluation of the monitored parameter(s) indicates that a disturbance has occurred or may occur in the electric power system, one or more disturbance reports may be generated. The disturbance report(s) may be delivered to at least one group of users, where each group includes at least one user. The “users” may be any person associated with an electric power system, including engineers, technicians, administrators, or any other people. The reports may be disseminated by the system to users who may analyze the reports, service the power system or for informational purposes.

The reports may differ in content and format. The reports can include general information, such as event number, event name, signal status and time of event occurrence. Also, disturbance reports may include time diagram overview, zoomed time diagrams, vector diagrams, and/or event recording. Analog and/or digital information may be included. In some embodiments, a total recording of all data may be presented. Sampled data and/or root mean square (RMS) may be included.

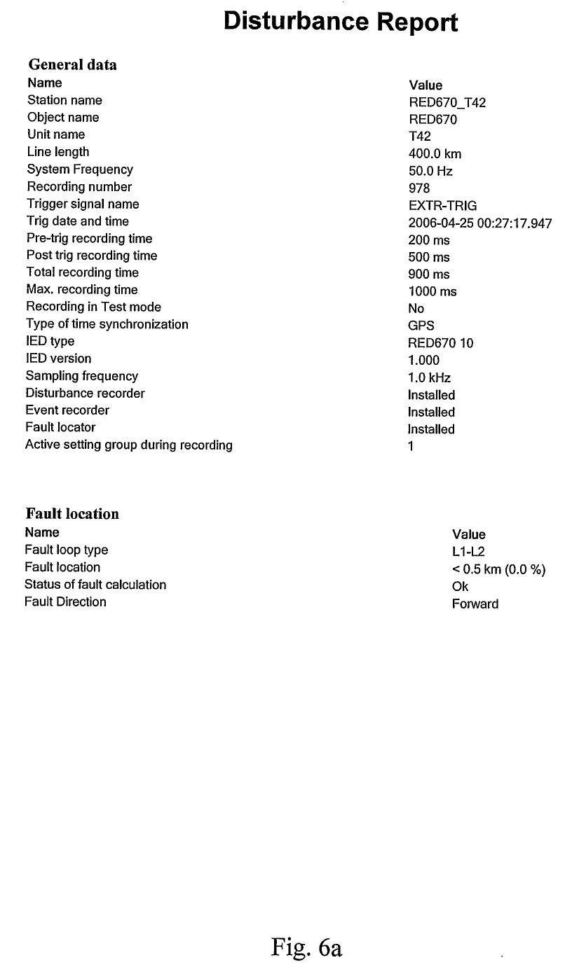

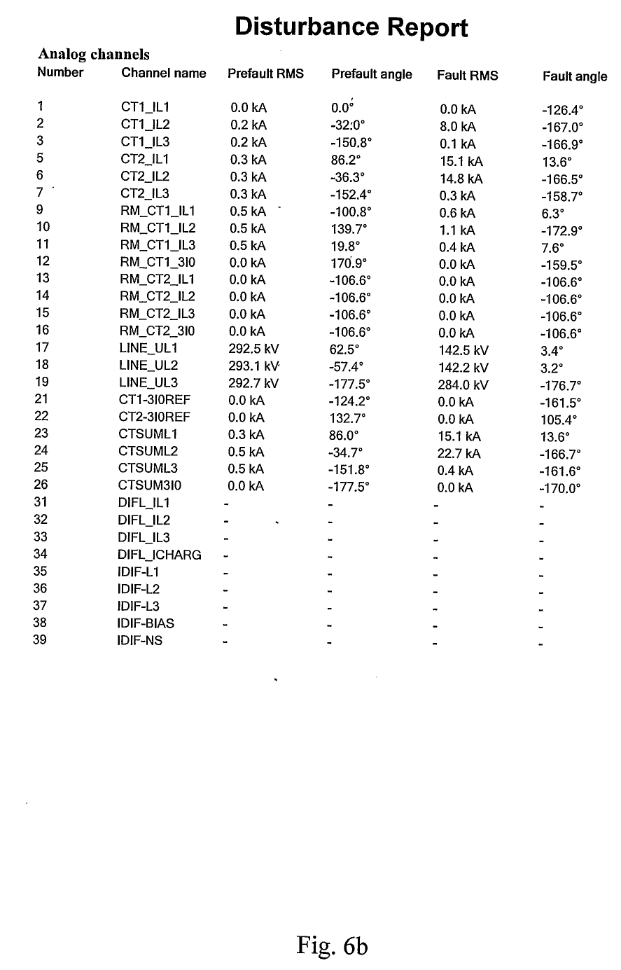

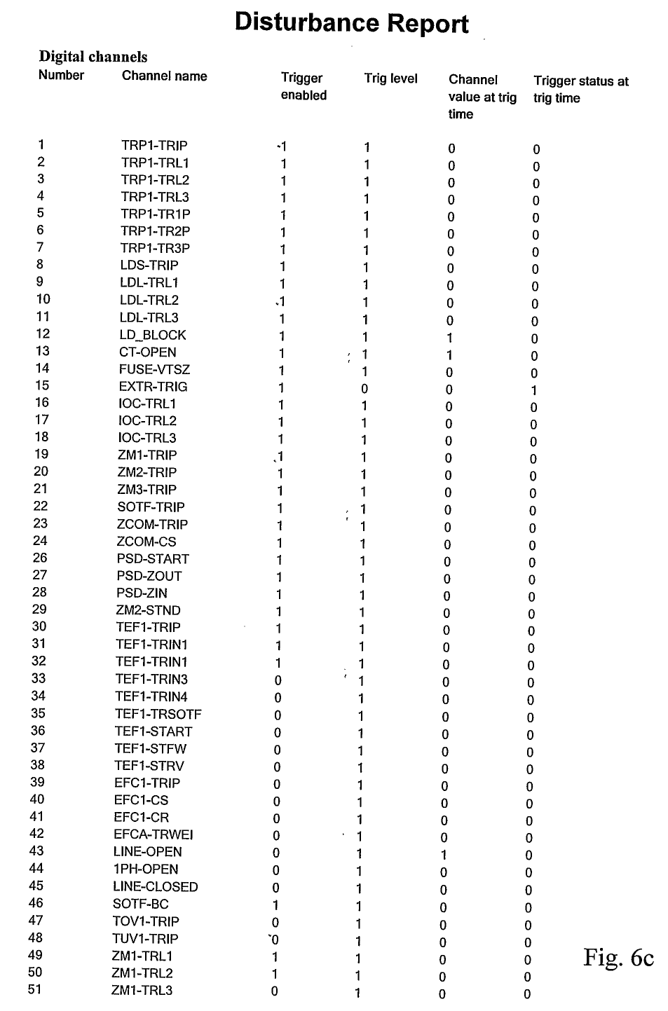

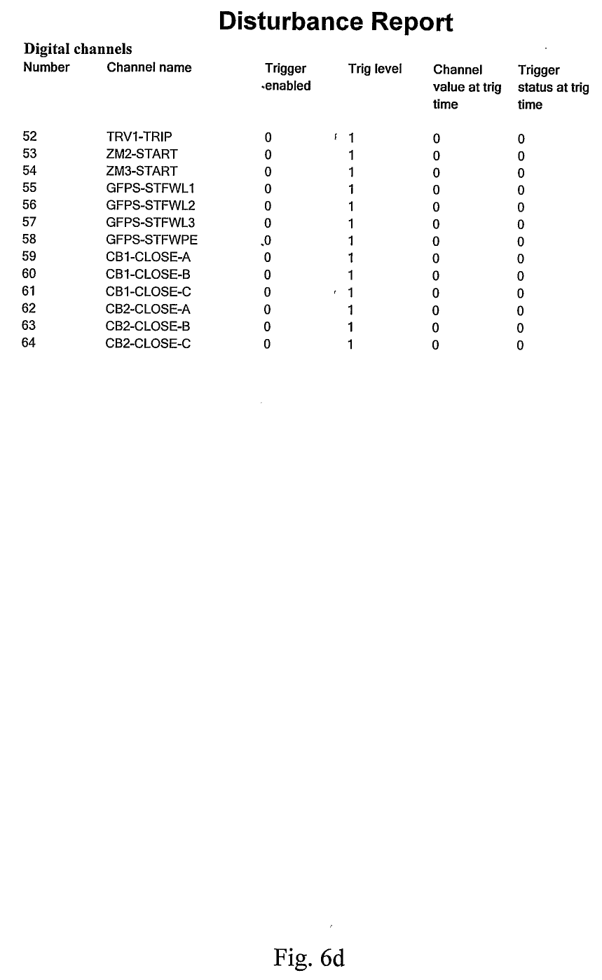

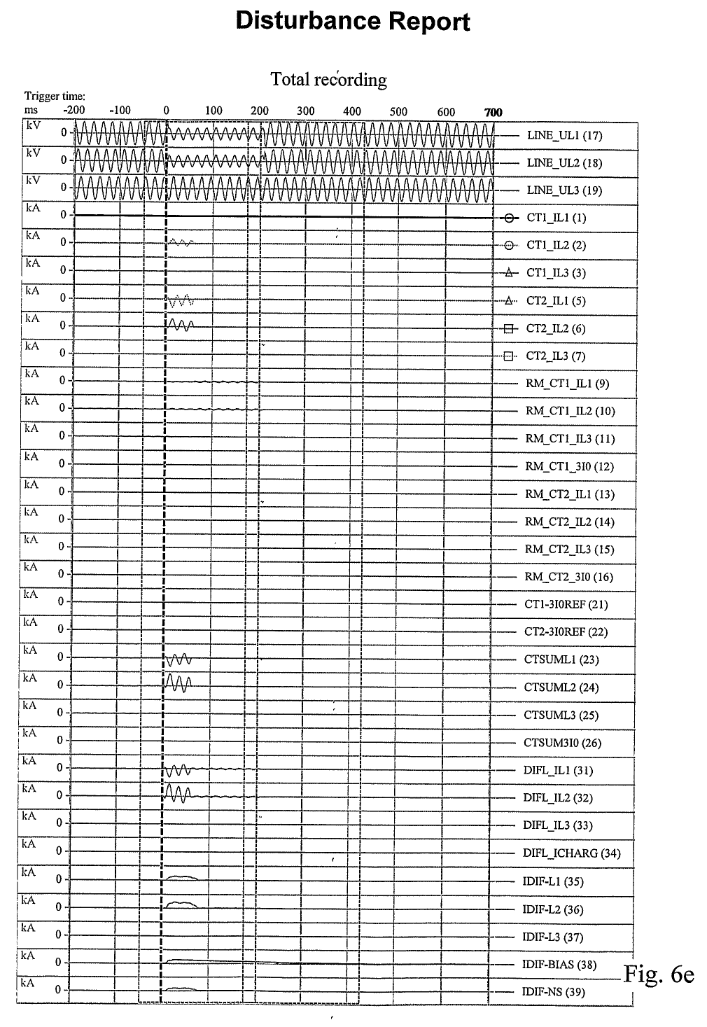

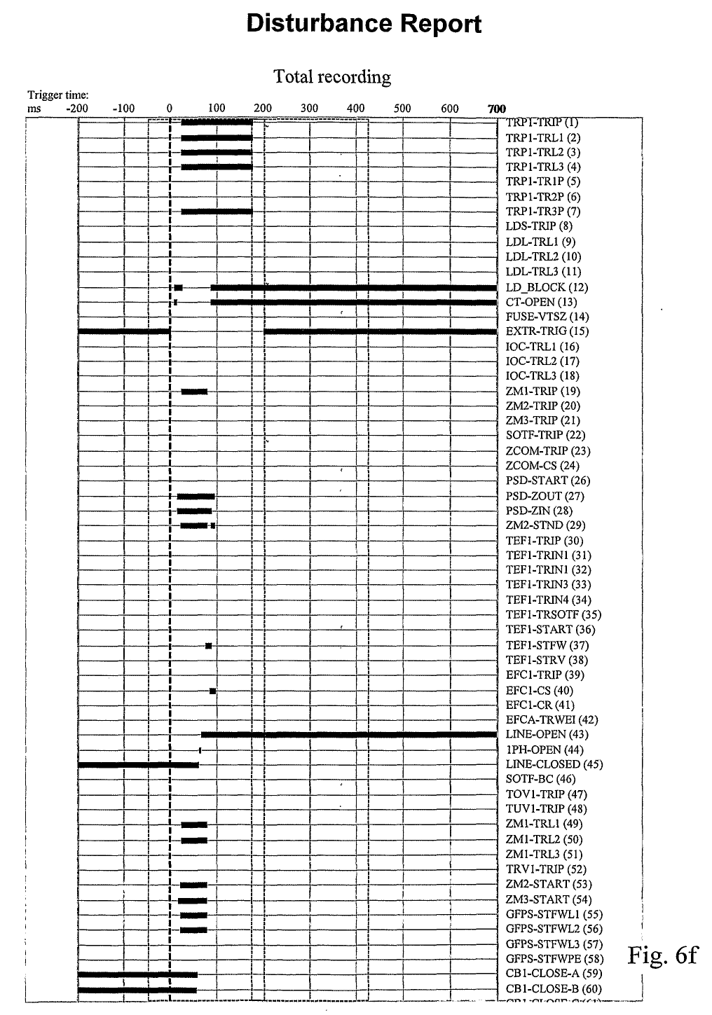

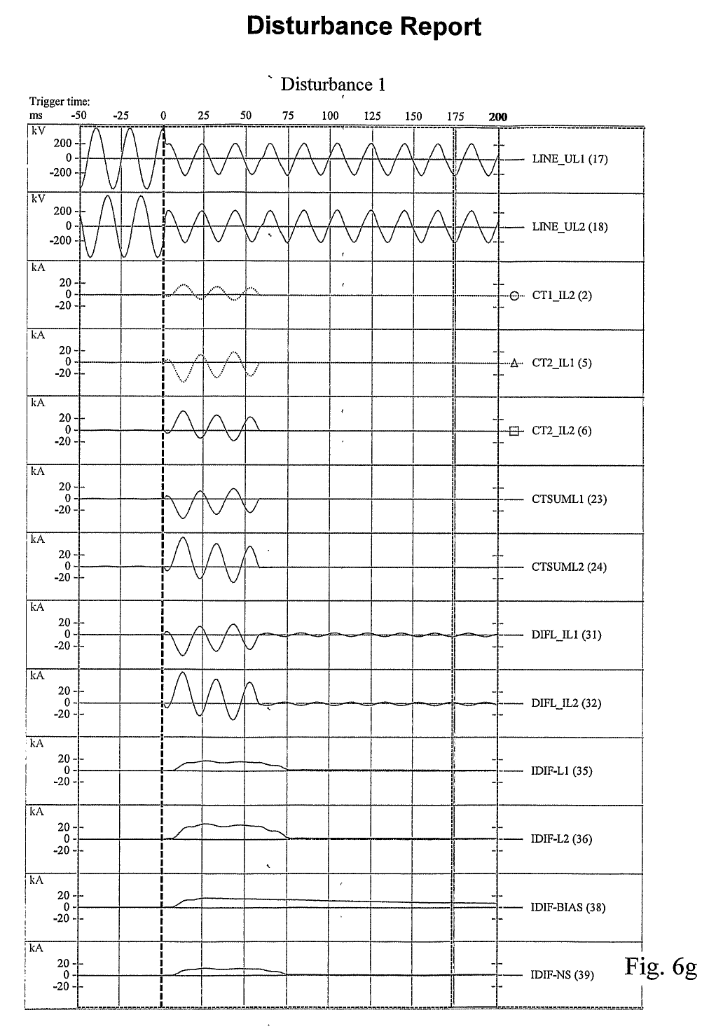

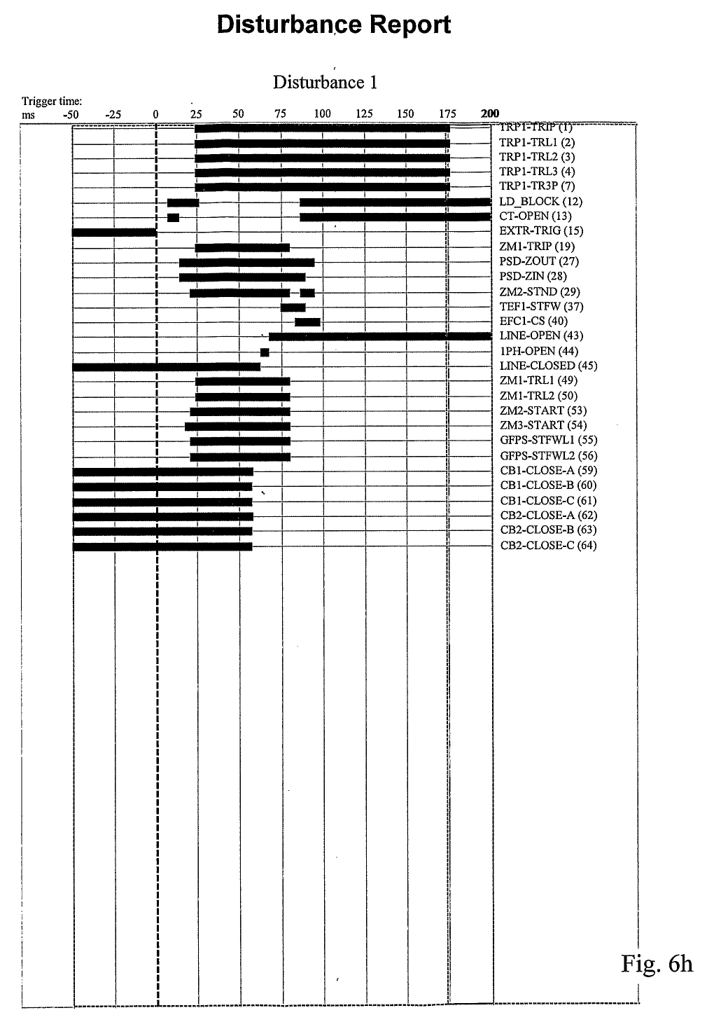

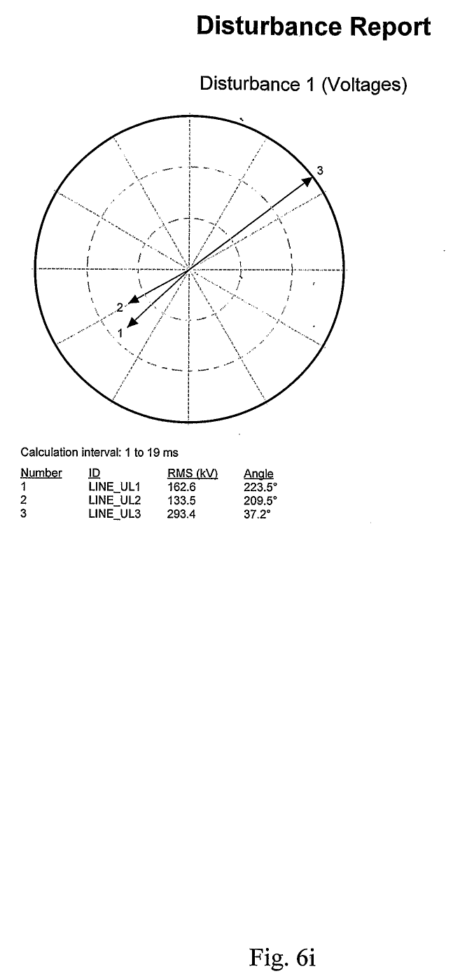

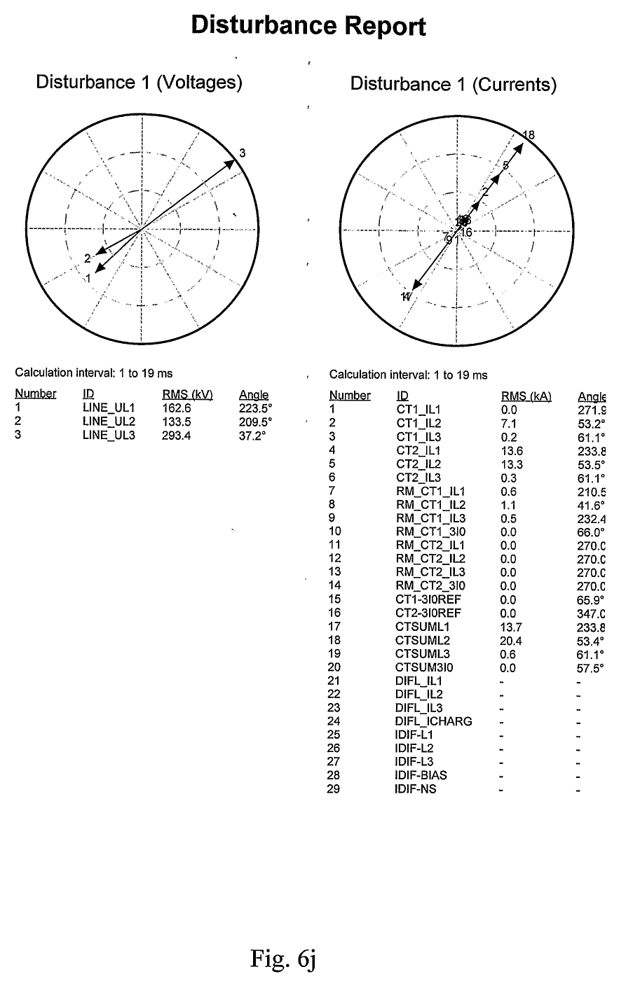

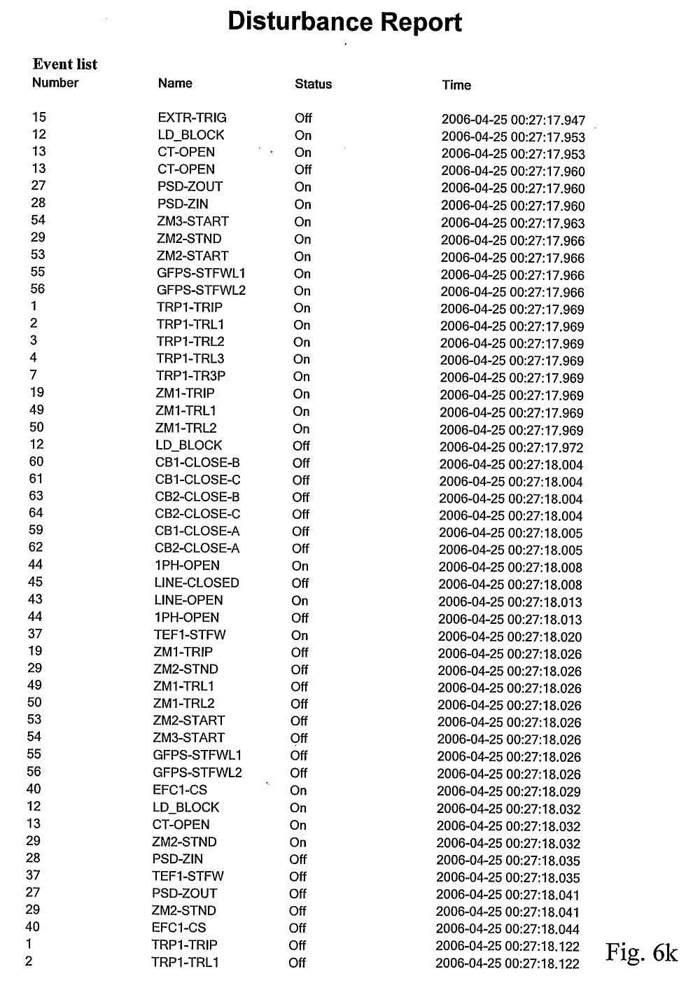

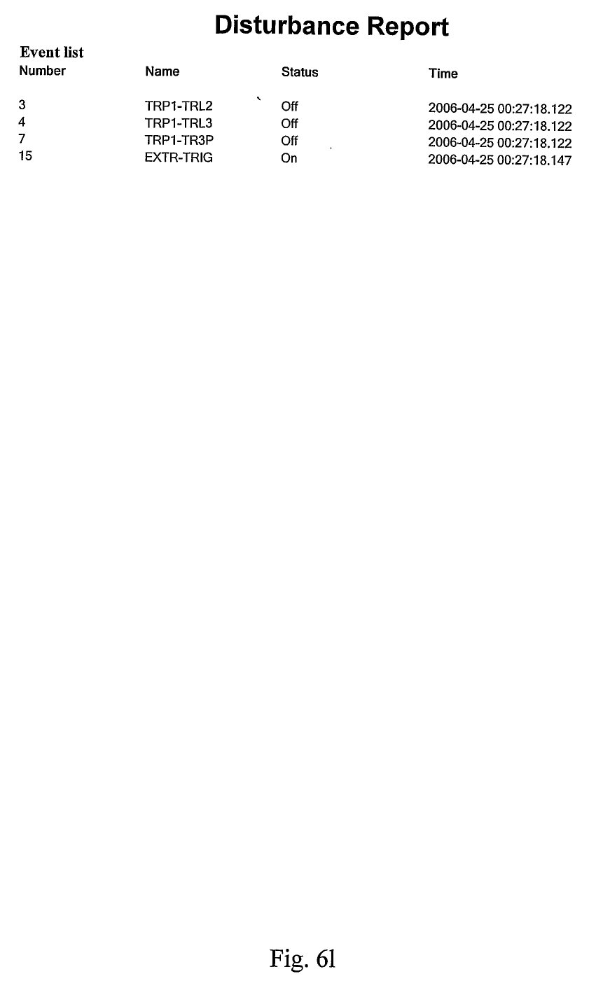

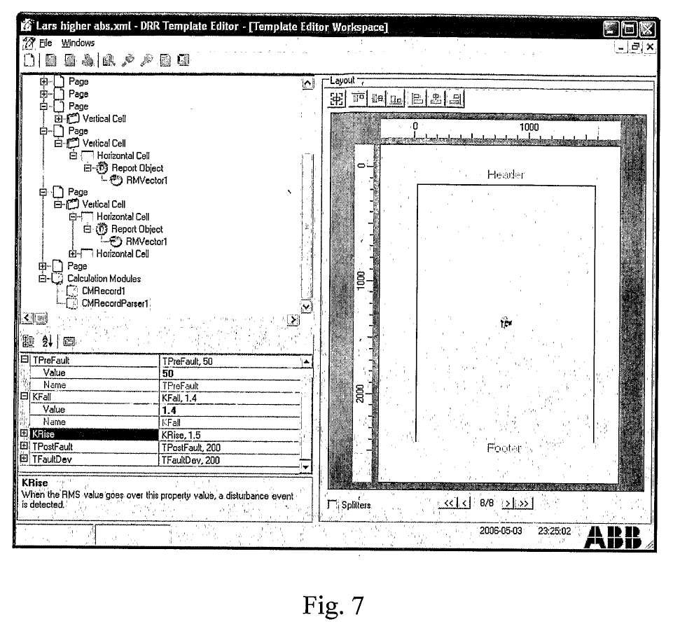

FIGS. 7a-6l represent pages of an embodiment of an event report that may be produced according to the present invention. FIG. 6a provides general data and fault locations. FIG. 6b provides values for analog channels, including channel number, name, and for selected channels prefault RMS, prefault angle, fault RMS and fault angle. FIGS. 6c and 6d provides digital channels, including channel name, trigger enabled, trigger level, channel value at trigger time, trigger status at trigger time. FIG. 6e provides a time diagram for selected analog channels. FIG. 6f represents binary indications for selected protection functions. FIG. 6g represents a zoomed time diagram focusing on a portion of the time diagram shown in FIG. 6e. FIG. 6h represents a zoomed binary indication diagram focusing on a portion of the graph shown in FIG. 6f. FIG. 6i represents a vector diagram for voltage over a 19 ms time period. FIG. 6j represents vector diagrams for voltage and current over a 19 ms time period. FIGS. 6k and 6l represent a list of events, including name, number, status and time of the status.

The information may include information typically forming a COMTRADE recording file, which is a commonly accepted standard format for recorded disturbance data. The COMTRADE file includes a configuration file (.cfg) that can include the number of channels utilized, channel name, units, sampling rate and/or according time, among other elements. The standard is defined in the IEEE standard. The COMTRADE file also includes a data file (.dat). The data file includes sampled data for each recorded channel and recorded stamp and/or time stamp. The COMTRADE file may optionally include a header file. The header file may include information concerning the IED, event recorder (ER), and/or trip value recorder (TVR), among other elements. An event recorder function in an IED may store event information from protection and control functions in the IED. It may also store internal self-supervision events from the IED. The trip value recorder function may store the RMS values of analog channels connected to the IED at the time that a disturbance recording is triggered (started) in the IED. The header file also typically includes the following information:

RecorderId—Id of the recorder, there might be multipole recorder functions in one IED;

TrigDateTime—Date and time of the Recording;

TrigChannel—what channel triggered (started) the recording;

TrigWhileIEDinTestMode—was the IED in Test mode during therecording;

TypeOfTimeSync—Indicates what time synchronization source (GPS, SNTP etc.) that was used to synchronize the real time clock in the IED;

FaultLocInst—indicates if there is a fault locator function in this IED;

LineLength—length of the power line (if the IED is protecting a line);

SystemFreq—System net frequency (50/60 Hz);

TotalRecordingTime—How long time is included in this recording;

PreTrigRecordingTime—How long time before the trigger event is included in the recording;

PreTrigRecordingTime—How long time before the trigger event is included in the recording;

PostFaultRecordingTime—How long time after the trigger event is included in the recording;

RecordingTimeLimitSetting—The setting in the IED mor maximum time to include in a recording;

SamplingFrequency—Sampling frequency of the analog channels in the recording;

IEDsourceType—Type of IED;

DisRecVerSW—Firmware version of the IED;

StationId—Identifier of the Substation;

ObjectId—Identifier of the objet (power line, transformer, generator, motor, busbar etc) that the IED is protecting;

IEDid—Identifier of the IED;

ActiveSettingGroup—What parameter set (for the protection functions in the IED) were active during the recording;

FaultLocCalculationStatus—Status of the fault location function in the IED (OK/Error), was the IED able to calculate a distance to the fault;

FaultLocFaultedLoop—What type of fault did the fault location function find (Phase(A/B/C) to Earth or Phase to Phase);

FaultLocDistanceToFault—How long line distance to fault did the fault location function calculate.

File formats other than COMTRADE may also be utilized.

In some embodiments, sub-disturbances within a recording may be presented. To help reduce extraneous information, non-disturbed channels may be suppressed. The report(s) may present data beginning prior to a disturbance. The report(s) may include an initial portion of each disturbance. In reports, voltage and current channels may be presented separately. Some disturbance report may include phasors. The phasors may be presented in tabular form. The phasors may include, for example, Analog Input Module (AIM), which includes data measured in the IED; Line Differential Communication Module (LDCM), which includes data measured in another IED and transferred via a communication module and optical fiber to the IED recording data; and Σ-block, which is a function in an IED to perform mathematical operations on two or more data channels connected to the IED.

Each member of a group of users may receive the reports having the same content and format. The format and/or content of the report delivered to each user in a group of users may vary. Similarly, the format and/or content of disturbance reports delivered to various groups of users may be similar or different. The information included in the report typically is defined for each user and/or group of users to which the res) arm delivered. Along these lines, certain users may analyze and or work to rectify certain aspects of a disturbance and would want to receive reports tailored to those aspects of disturbances. Examples of users can include management, research, and maintenance personnel, among others.

The results of a disturbance analysis may be documented in a disturbance report that can include facts and conclusions derived from these facts. For example, reports may include differentially filtered and processed data for delivery to different users and/or groups of users according to specific needs for information. A typical disturbance report may include both the synthesis of obtained relevant information and calculated data, such as fault clearance time, fault location, interrupted power, and non-delivered energy. The report may also include a description of the happenings and conclusions along with recommended action items to correct problem areas. In some instances, the report may only include data relevant to the fault or changes in data relevant to the fault.

After generating disturbance reports, the present invention may automatically distribute the reports. The reports may be distributed to users via e-mall, text message, facsimile and/or any other means. The reports may be sent to personal computers, mobile phones, personal digital assistants and/or other devices. The automatic filtering, preanalysis, and report generation and distribution that can be carried out according to the present invention can help to reduce the time required to clear faults. Reports can be viewed on a screen, printed out and/or otherwise reviewed.

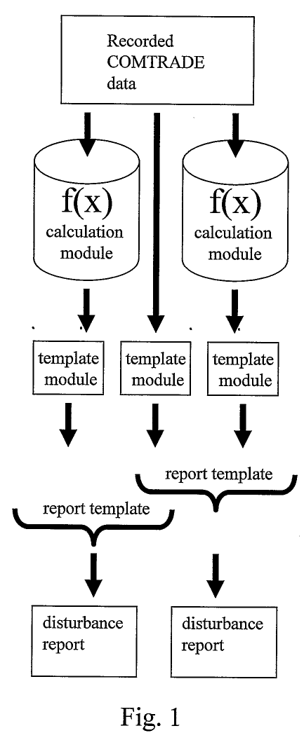

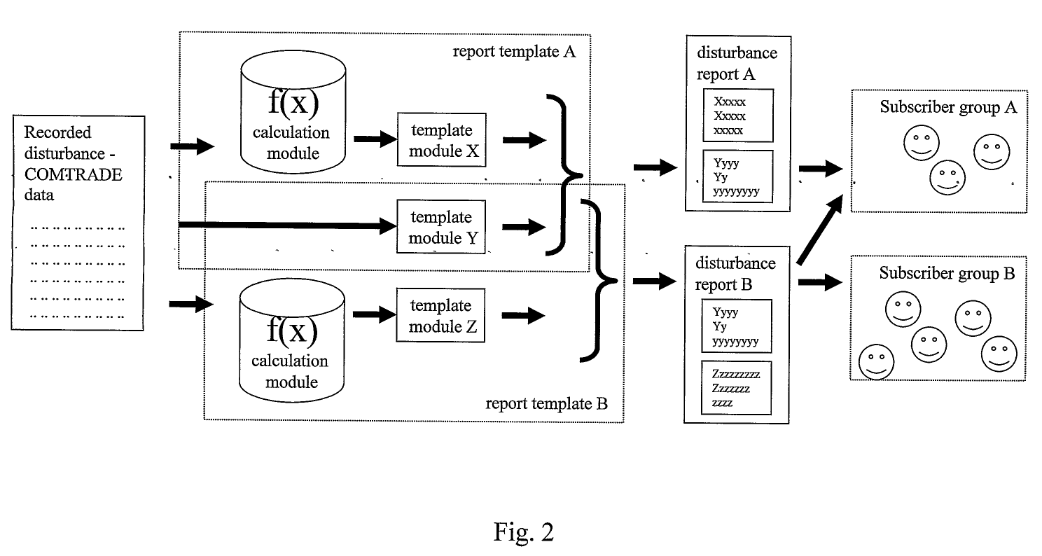

Solutions according to the present invention may combine an event trigged automated report generator with a means to automatically send reports based on templates to a set of subscribers. The reports are based on recorded disturbance data and on templates that can be unique to meet the needs of each group of report subscribers. There are ready-to-use templates as well as user-defined templates edited in a template editor. FIGS. 1 and 2 represent schematic illustrations of two embodiments of systems according to the present invention.

An automatic disturbance report system according to the present invention may include an application portion that may be installed and run on a personal computer. The computer may be installed at an electric power utility station or control center. The computer may alternatively be remote from such locations. The application may communicate with relay protection devices that transmit data, which may include distance data and/or notification on newly occurring disturbances, such as through a disturbance event.

A system according to the present invention may include one or more modules to carry out one or more aspects of report generation described herein. For example, a system according to the present invention may include a calculation module. The calculation module can record disturbance data. The calculation module may include criteria to identify relevant date subsets. For example, the calculation module the calculation module may compare monitored values with baseline or target values to identify disturbances. A calculation module according to the present invention may make calculations employing include commonly utilized electric power calculation methods. The calculation modules may process data presented in report modules. For example, the data can include RMS values, harmonics, symmetrical components, impedance, and/or power, among others.

A calculation module according to the present invention may include criteria to identify relevant data subsets. For example, the calculation module may find which measured analog or binary channels that diverge from normal operating values or a limited time window where a disturbance occurs. The calculation modules may also perform other data processing functions. For example, a calculation module could detect sudden changes in RMS value of a recorded parameter, such as voltage or current, and thereby decide that at this time in the recording something interesting for the receiver of the report may have occurred. The detection of this event may result in a period of time before and after the time when the change was detected being presented as an event in the generated report. Calculation modules could calculate impede and a report plot the impedance in an R-X plane.

A system according to the present invention may include a recording module that can receive values for electric system parameters and transmit the values to calculation module(s).

After the calculation module(s) detects changes in at least one electric system parameter and determines that an event has occurred, the calculation module(s) may generate at least one disturbance signal. A system according to the present invention may include at least one report module operative to receive the disturbance signal(s), generate at least one report and forward the report to at least one group of users including at least one user. The report may include the information as described above.

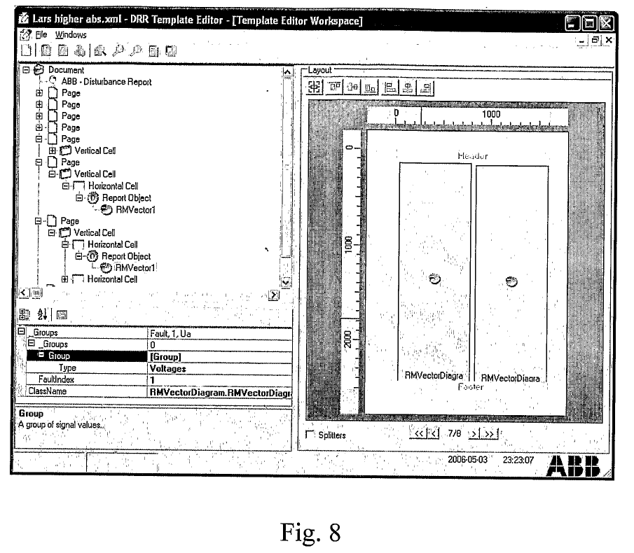

A report module may include one or more template modules. The report template may include support to create and edit new report templates as well as ready-to-use report templates. A report module according to the present invention may include palettes of options for defining a report template. For example, any of the parameters or calculations discussed above may be selected for inclusion in a report. Report modules may define reports include specific aspects of disturbance data. For example, reports may include an analog graph of a current or voltage channel or vector diagram of a three-phase system at one or more points in time. FIG. 7 illustrates a screen shot showing an embodiment of a template editor, showing configuration of the calculation module for detecting an event in the set of recorded data. FIG. 8 a screen shot showing an embodiment of a template editor, showing configuration of a vector diagram for voltages at the first detected (Fault 1) event in a set of recorded data.

The embodiments illustrated and discussed in this specification are intended only to teach those skilled in the art the best way known to the inventors to make and use the invention. Nothing in this specification should be considered as limiting the scope of the present invention. All examples presented are representative and non-limiting. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1-21. (canceled)

22. A method for automated analysis of events in an electric power system and dissemination of a report file, the method comprising:
receiving recorded values of at least one monitored parameter of an electric power system, where the at least one parameter includes at least one member selected from the group comprising voltage, current, or binary information regarding power system components;
detecting changes in the values of said parameter;
determining if an event has occurred in the system based on the detected changes;
if an event has occurred, further performing the steps of
generating a report file comprising selected recorded values of the parameter in a time period before and after the event; and
automatically sending the report file to at least one predefined group of users comprising at least one user.

23. The method according to claim 22, wherein the step of detecting changes in the values comprises comparing parameter values with baseline or target values or ranges of values and an event is determined based on how the parameter values differ from the baseline or target values or range of values.

24. The method according to claim 23, wherein an event is determined if the parameter values differ from the baseline or target values or range of values.

25. The method according to claim 23, wherein an event is determined based on the trend in difference between the parameter values and the baseline or target values or range of values.

26. The method according to claim 22, wherein a recorded value may be an RMS value of a parameter and an event is determined if there is a sudden change in this RMS value.

27. The method according to claim 22, wherein the power system components comprise at least one member selected from the group comprising breakers, disconnectors, and earthing switches.

28. The method according to claim 22, wherein the user is able to view the report file by using general & standard software available on the market

29. The method according to claim 22, wherein the at least one report file is generated in a plurality of predefined formats.

30. The method according to claim 22, wherein different types of report files are sent to the different predefined groups of users.

31. The method according to claim 29, wherein each group receives the at least one report file in a different predefined format.

32. The method according to claim 29, wherein the plurality of predefined formats vary in at least one of information included in the report file or layout of the report file.

33. The method according to claim 22, wherein the at least one report file is generated in a format viewable on a personal computer, a mobile phone, or a personal digital assistant.

34. The method according to claim 22, wherein the at least one report file is generated in a report module and the at least one event is determined to have occurred in a calculation module.

35. The method according to claim 34, wherein multiple calculation modules determine the occurrence of the at least one event.

36. The method according to claim 35, wherein the multiple calculation modules forward data to one report module.

37. The method according to claim 34, wherein multiple report modules receive data from one calculation module.

38. The method according to claim 22, wherein the at least one parameter of an electric power system comprises at least one of current of voltage samples.

39. The method according to claim 22, wherein at least one user defines the format of at least one report file.

40. The method according to claim 22, wherein determining that at least one event has occurred comprises extracting data from monitoring equipment monitoring the power system.

41. The method according to claim 22, wherein the at least one event comprises a fault.

42. A system for automated analysis of events in an electric power system and dissemination of a report file, the system comprising:
at least one recording module operative to receive and record values of at least one monitored parameter of the electric power system, where the at least one parameter includes at least one member selected from the group comprising voltage, current, or binary information regarding power system components;
at least one calculation module operative to receive said recorded values of at least one monitored parameter, detect changes in the values of said parameter, determine if an event has occurred in the system based on the detected changes and generate at least one event signal; and
at least one report module operative to receive the at least one event signal from the at least one calculation module, generate at least one report file comprising recorded data of the parameter provided in a time period before and after the event and automatically send the report file to at least one predefined group of users comprising at least one user.

43. A computer program product, comprising:
a computer readable medium; and
computer program instructions, recorded on the computer readable medium, executable by a processor, for performing the steps of
receiving recorded values of at least one monitored parameter of an electric power system, where the at least one parameter includes at least one member selected from the group comprising voltage, current, or binary information regarding power system components;
detecting changes in the values of said parameter;
determining if an event has occurred in the system based on the detected changes,
if an event has occurred
generating at least one report file comprising selected recorded values of the parameter in a time period before and after the event; and
automatically sending the at least one report file to at least one predefined group of users comprising at least one user.
